(19) United States
(12) Patent Application Publication
(10) Pub. No.: US 2019/0189591 A1
(43) Pub. Date: Jun. 20, 2019

(54) SEMICONDUCTOR STORAGE CUBE WITH ENHANCED SIDEWALL PLANARITY

(71) Applicant: SANDISK INFORMATION TECHNOLOGY (SHANGHAI) CO., LTD., Shanghai (CN)

(72) Inventors: Yazhou Zhang, Shanghai (CN); Chin Tien Chiu, Taichung City (TW); Cong Zhang, Shanghai (CN)

(73) Assignee: SANDISK INFORMATION TECHNOLOGY (SHANGHAI) CO., LTD ., Shanghai (CN)

(21) Appl. No.: 15/907,491

(22) Filed: Feb. 28, 2018

(30) Foreign Application Priority Data
Dec. 20, 2017 (CN) 201711389696.1

(51) Int. Cl. H01L 25/065; H01L 23/00; H01L 23/528

(52) U.S. Cl. CPC H01L 25/0657; H01L 24/46; H01L 24/05; H01L 23/528; H01L 2225/06565; H01L 2224/04042; H01L 2224/4918; H01L 2224/14133; H01L 2225/06506; H01L 24/14

(57) ABSTRACT

A semiconductor cube is disclosed including one or more highly planar vertical sidewalls on which to form a pattern of electrical traces. The semiconductor cube may be fabricated from a semiconductor cube assembly including a vertical semiconductor die stack and a pair of wire bond landing blocks. The vertical semiconductor die stack may be wire bonded off of first and second opposed edges to different levels of the first and second wire bond landing blocks. Once all wire bonds are formed, the semiconductor cube assembly may be encapsulated in mold compound. The mold compound may then be cut to separate the semiconductor die stack from the wire bond landing blocks, leaving the wire bonds exposed in a sidewall of the semiconductor cube.

### BACKGROUND

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While many varied packaging configurations are known, a recent design relates to a semiconductor flash cube having a vertically stacked array of semiconductor die. The die bond pads of these die are extended out to a vertical edge of the cube, and a pattern of electrical traces are then formed on the vertical edge by thin film deposition and photolithography coupling the edge-connected die bond pads to each other and a pattern of solder balls on a top or bottom surface of the cube. The solder balls may then be soldered to a host device such as a printed circuit board for memory storage by the host device.

Typical semiconductor cubes include a substrate electrically connected to the memory die stack as by wire bonding for transferring signals between the memory die stack and a host device. Flash cubes such as described above provide an advantage in that a conventional substrate may be omitted, thereby providing improving storage capacity for a given size package.

However, it is important in flash cubes that the semiconductor die in the die stack be precisely aligned. In particular, in forming the electrical lead pattern on the vertical edge, if the die together do not form a highly aligned planar surface, the lead pattern may not be properly formed on the edge and may not function properly. Given that there are manufacturing tolerances in the sizes of semiconductor die, and given that semiconductor die are stacked with a DAF layer which can allow slight shifting of the die relative to each other before curing, it is difficult to provide the vertical edge with the needed level of planarity.

### DESCRIPTION OF THE DRAWINGS

FIG. 1 is a flowchart of the overall fabrication process of semiconductor cube according to embodiments of the present technology.

FIG. 2 is a perspective view of a semiconductor cube assembly at a first intermediate step in the fabrication process according to an embodiment of the present technology.

FIG. 3 is a front view of a semiconductor cube assembly at a second intermediate step in the fabrication process according to an embodiment of the present technology.

FIG. 4 is a front view of a semiconductor cube assembly at a third intermediate step in the fabrication process according to an embodiment of the present technology.

FIG. 5 is a side view of a semiconductor assembly cube at a fourth intermediate step in the fabrication process according to an embodiment of the present technology.

FIG. 5A is a side view of a semiconductor assembly cube at the fourth intermediate step in the fabrication process according to an alternative embodiment of the present technology.

FIG. 6 is a perspective view of a singulated semiconductor cube according to an embodiment of the present technology.

FIG. 7 is a perspective view of a finished semiconductor cube according to an embodiment of the present technology.

FIGS. 8-10 are perspective views of a semiconductor cube assembly and finished semiconductor cube according an alternative embodiment of the present technology.

FIG. 11 is a flowchart of the overall fabrication process of semiconductor cube according to a further alternative embodiment of the present technology.

FIG. 12 is a front view of a semiconductor cube assembly at an intermediate step in the fabrication process according to the further alternative embodiment of the present technology.

FIG. 13 is a perspective view of a singulated semiconductor cube according to the further alternative embodiment of the present technology.

FIG. 14 is a perspective view of a finished semiconductor cube according to the further alternative embodiment of the present technology.

### DETAILED DESCRIPTION

The present technology will now be described with reference to the figures, which in embodiments relate to a semiconductor cube including one or more highly planar vertical sidewalls on which to form a pattern of electrical traces. The semiconductor cube may be fabricated from a semiconductor cube assembly including a vertical semiconductor die stack and a pair of wire bond landing blocks. The vertical semiconductor die stack may be wire bonded off of first and second opposed edges to different levels of the first and second wire bond landing blocks. Once all wire bonds are formed, the semiconductor cube assembly may be encapsulated in mold compound.

Thereafter, the semiconductor cube assembly may be cut vertically to sever both landing block assemblies, leaving just the encapsulated semiconductor die stack. The severed landing block assemblies may be discarded. The vertical cuts at the opposed sides of the semiconductor die stack form highly planar sidewalls in the molding compound. The vertical cuts also sever the wire bonds off of both edges of the semiconductor die in the die stack, with ends of the severed wire bonds being exposed at the cut planar sidewalls of the molding compound. Thereafter, a pattern of electrical traces may be formed on the highly planar sidewalls in contact with the exposed wire bonds. The electrical traces connect the die stack to a controller die, which in turn may be coupled to a host device, such as for example by solder balls or solder bumps.

It is understood that the present technology may be embodied in many different forms and should not be construed as being limited to the embodiments set forth herein. Rather, these embodiments are provided so that this disclosure will be thorough and complete and will fully convey the technology to those skilled in the art. Indeed, the technology is intended to cover alternatives, modifications and equivalents of these embodiments, which are included within the scope and spirit of the technology as defined by the appended claims. Furthermore, in the following detailed description of the present technology, numerous specific details are set forth in order to provide a thorough understanding of the present technology. However, it will be clear to those of ordinary skill in the art that the present technology may be practiced without such specific details.

The terms “top” and “bottom,” “upper” and “lower” and “vertical” and “horizontal” as may be used herein are by way of example and illustrative purposes only, and are not meant to limit the description of the technology inasmuch as the referenced item can be exchanged in position and orientation. Also, as used herein, the terms “substantially,” “approximately” and/or “about” mean that the specified dimension or parameter may be varied within an acceptable manufacturing tolerance for a given application. In one embodiment, the acceptable manufacturing tolerance is ±0.25% of a defined dimension.

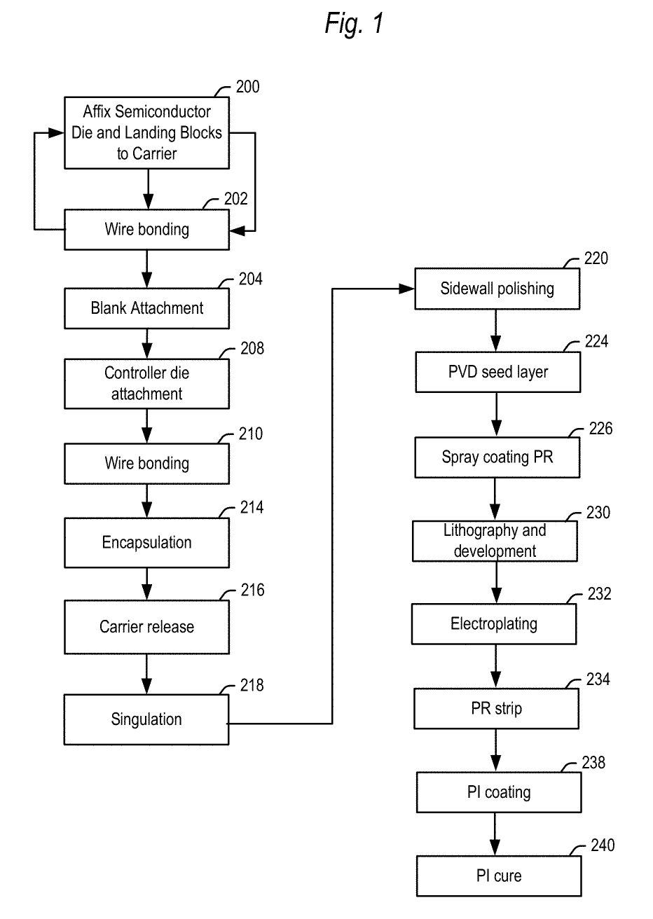

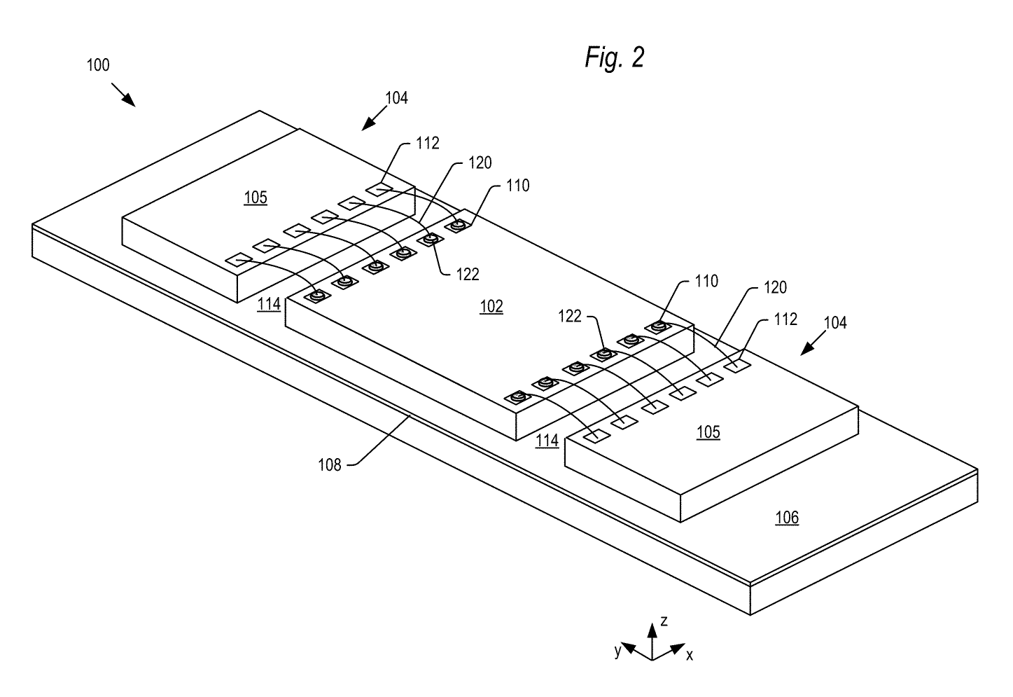

An embodiment of the present technology will now be explained with reference to the flowchart of FIG. 1 and the perspective and front views of FIGS. 2-7. In step 200, a semiconductor cube assembly 100 may be formed by mounting a number of semiconductor die 102, and a corresponding number of layers of a pair of wire bond landing blocks 104, onto a carrier 106 as shown in FIG. 2. The carrier 106 may include an adhesive release layer 108 for temporarily holding the semiconductor die 102 and wire bond landing blocks 104 on the carrier as explained below.

The semiconductor die 102 may for example be processed to include integrated circuits to form die 102 into memory die such a NAND flash memory die, but other types of die 102 may be used. These other types of semiconductor die include but are not limited to RAM such as an SDRAM. In the embodiments shown in the figures, semiconductor die 102 include a row of die bond pads 110 at opposed edges of the semiconductor die 102. However, as explained, the semiconductor die 102 may include die bond pads 110 off of a single edge in further embodiments.

The wire bond landing blocks 104 on either side of the semiconductor die 102 may for example be formed of multiple layers 105 of aluminum (a first layer 105 of a pair of landing blocks 104 being shown in FIG. 2). The layers 105 of landing blocks 104 may be processed to include pads 112 for receiving wire bonds as explained below. The wire bond landing blocks 104 are provided for the purpose of providing a physical landing for wire bonds formed off of die bond pads 110 of the semiconductor die 102. The wire bond landing blocks 104 and pads 112 are not provided to receive or communicate any electrical signals. As such, landing blocks 104 may simply be formed of one or more layers 105 of solid aluminum. It is understood that the landing blocks 104 be formed of a variety of other materials, including for example other metals, polymers or ceramics.

The pads 110 may preferably be formed of a metal such as copper or aluminum well-suited for receiving a wire bond in a conventional wire bond process is explained below. Each pad 112 may align in the y-direction with a corresponding die bond pad 110. While a single row of pads 112 are shown facing the semiconductor die 102, each layer of each landing block 104 may include pads 110 on opposed edges in further embodiments. In such embodiments, the pads 110 closest to die 102 may receive wire bonds, and the second group of pads 110 farthest from die 102 may remain unused.

In embodiments, the layers 105 of landing blocks 104 may have the same thickness as die 102, though the landing block layers 105 may be thinner or thicker than die 102 in further embodiments. The layers 105 of landing block 104 may be separated from the semiconductor die 102 on the carrier 106 along the y-direction by space 114 on either side of the die 102. The spaces 114 may be 1 mm to 10 mm wide, though they may be wider or narrower than that in further embodiments.

In step 202, wire bonds 120 may be formed between the die bond pads 110 on die 102 and the pads 112 on the layers 105. Wire bonds 120 may be made for example of gold, and formed according to a number of schemes. However, in one embodiment, a wire bond capillary (not shown) forms a ball bump 122 on a first die bond pad 110 of die 102. From there, the wire bond capillary pays out wire and forms a stitch bond on a corresponding pad 112 of a layer 105. The wire bond capillary may then break the wire, move along the x-direction to the next die bond pad 110, and repeat the process until all wire bonds 120 are formed between the die bond pads 110 and the corresponding pads 112. The process may then be repeated for the opposed row of die bond pads 110 on die 102. As noted, wire bonds 120 may be formed by other methods in further embodiments.

It is understood that the number of die bond pads 110 and corresponding pads 112 is shown for illustrative purposes only, and there may be many more die bond pads 110, pads 112 and wire bonds 120 in further embodiments. In the embodiments shown in the figures, semiconductor die 102 include a pair of rows of die bond pads 110 at opposed edges of the die 102. However, in embodiments, die 102 may include a single row of die bond pads 110. In such embodiments, there may be a single wire bond landing block 104 that receives wire bonds from the single row of the die bond pads 110.

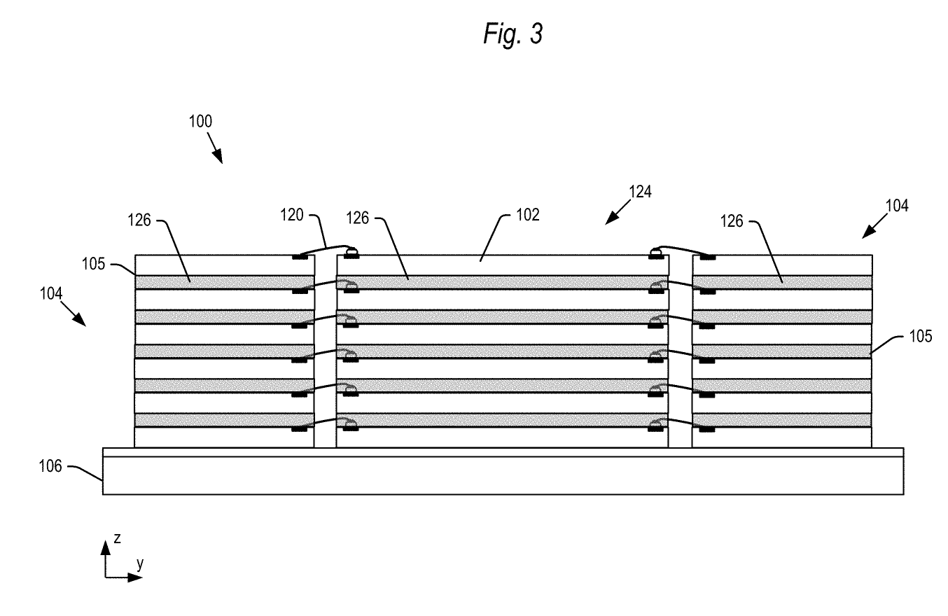

As indicated in the flowchart of FIG. 1 and shown in the front view of FIG. 3, steps 200 and 202 may be repeated to form a die stack 124 including multiple die 102, and wire bond landing blocks 104 including multiple layers 105. In particular, after a die 102 and a layer 105 are mounted on carrier 106 and wire bonded, the wire bonds 120 may be encased in a FOD (film on die) layer 126. Thereafter, the next semiconductor die 102 and layer 105 of landing blocks 104 may be mounted on the FOD layer 126. FOD layer 126 is provided to space the die 102 and layers 105 of landing blocks 104 leave sufficient room along the z-direction for wire bonds 120. The number of layers 105 in landing blocks 104 and die 102 in stack 124 is shown in FIG. 3 by way of example only, and there may be fewer or greater numbers of layers 105 and die 102 in further embodiments.

While the die 102 in stack 124 may be stacked on top of each other in the z-direction with reasonable tolerances, there is no requirement that the vertical edges of the respective die 102 precisely align with each other in vertical planes. This is in contrast to conventional semiconductor flash cubes, where one or more vertical edges needs to be aligned in a plane as discussed in the Background section.

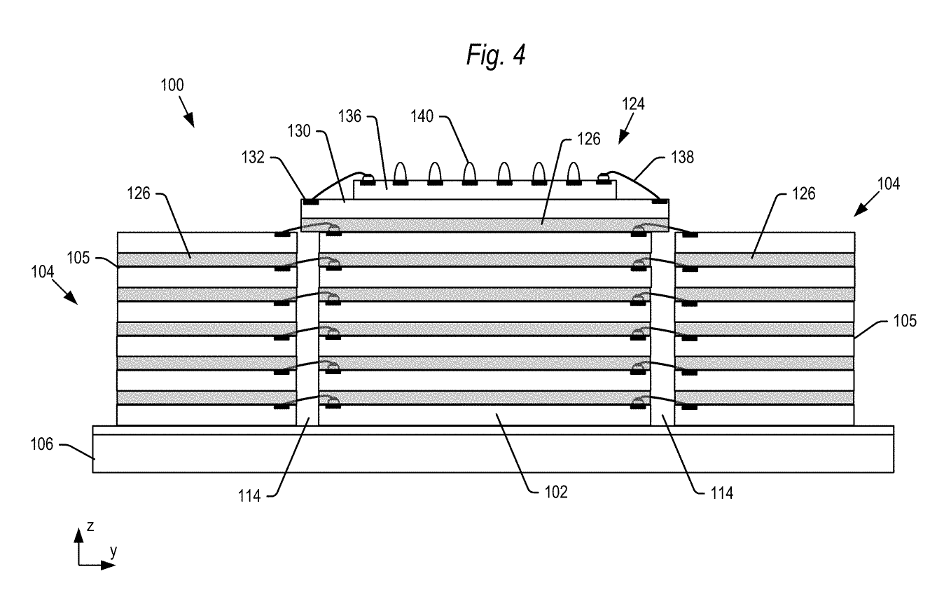

In step 204, a blank 130 may be affixed to the uppermost layer of FOD 126 as shown in FIG. 4. Blank 130 may be formed for example of aluminum, but may be formed of other materials in further embodiments including other metals, polymers and ceramics. Blank 130 may be formed with a row of pads 132 in the x-direction (into the page of FIG. 4) at opposed edges for receiving a wire bond as explained below. Pads 132 may be formed of copper, aluminum or other material well-suited for receiving a wire bond. The blank 130 any pads 132 may be sized and positioned so that the pads 132 overlie the spaces 114 in the z-direction between the wire bond landing blocks 104 and the die stack 124.

In step 208, a controller die 136 may be affixed to an upper surface of blank 130, for example via a DAF (die attach film) layer on a bottom surface of the controller die 136. The controller die 136 may for example be an ASIC, but may be other types of controllers in further embodiments. As explained below, the controller die 136 may be electrically connected to the semiconductor die 102 in stack 124. As is also shown in FIG. 4, the controller die 136 may be wire bonded to the pads 132 of blank 130 using wire bonds 138 in step 210. Wire bonds 138 may be formed on opposed edges of controller die 136 using a wire bond capillary (not shown) as described above.

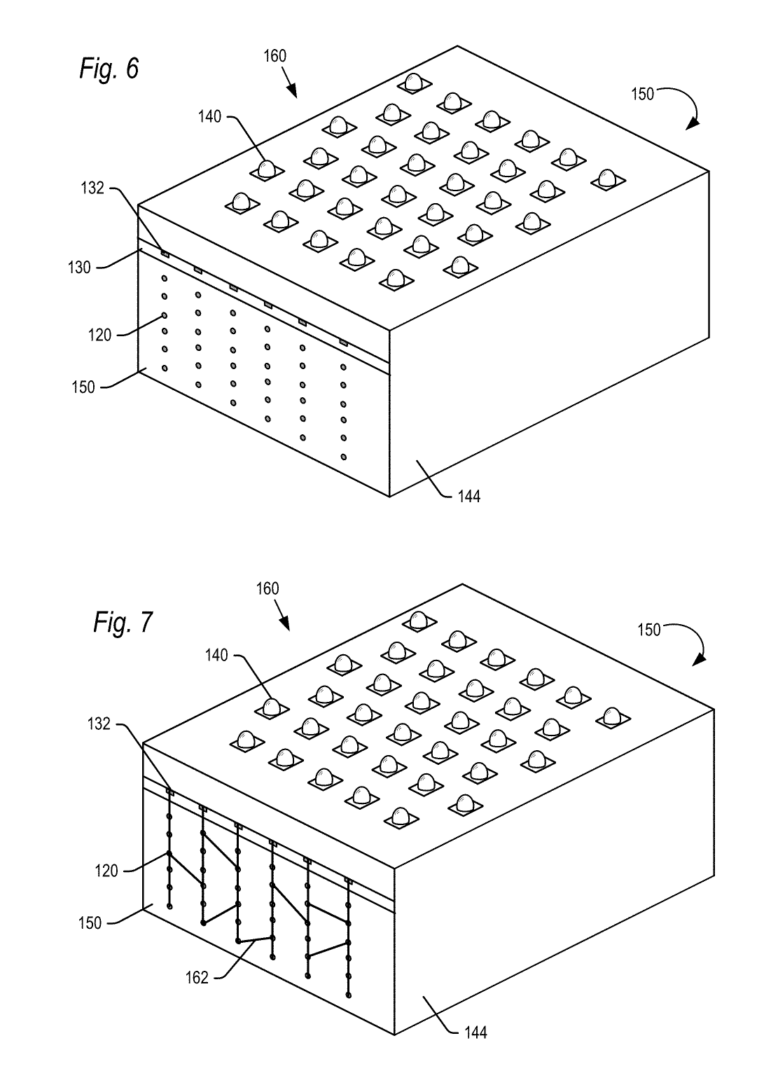

An upper surface of controller die 136 may include contact pads for receiving a grid of solder bumps 140 shown for example in the front view of FIG. 4 and the perspective view of FIG. 6. As explained below, the solder bumps 140 may be used to transfer signals between the control die 136 and a host device to which the semiconductor cube is affixed.

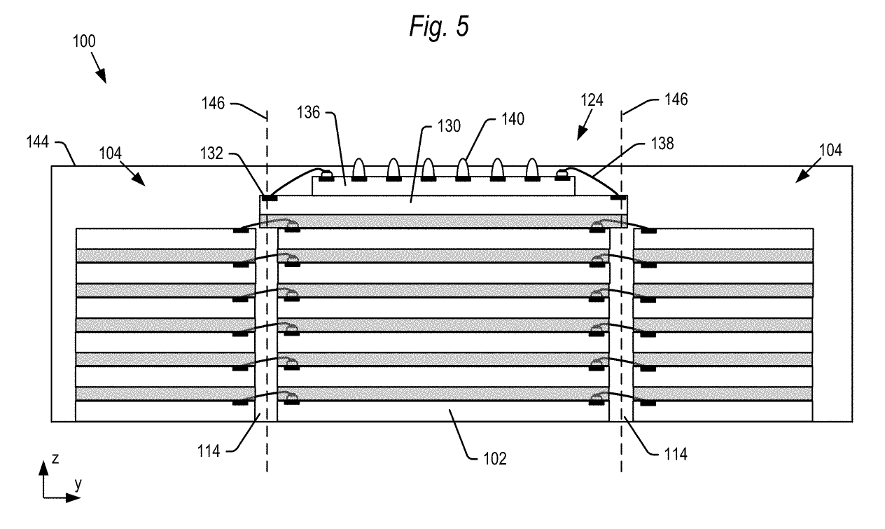

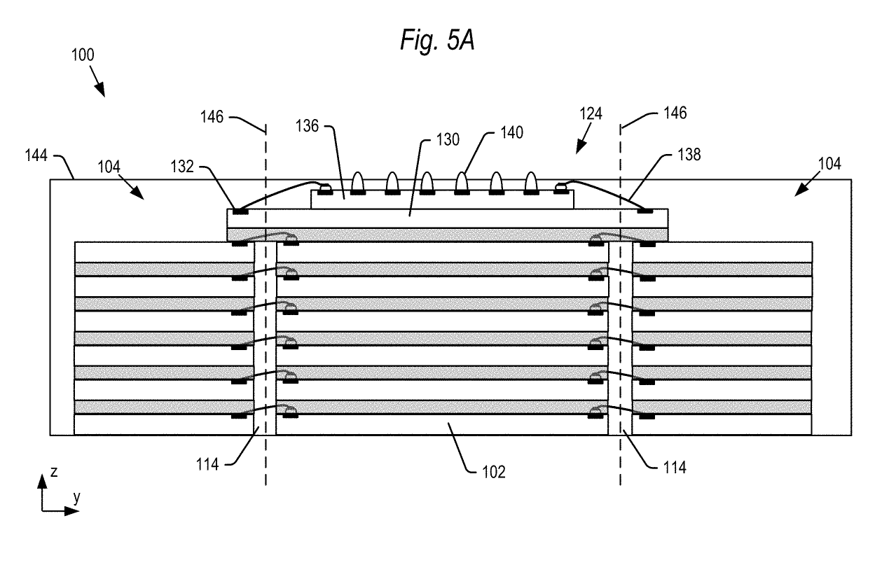

In step 214, the semiconductor cube assembly 100 may be encapsulated in a mold compound 144 as shown for example in the front view of FIG. 5. Mold compound 144 may provide a protective enclosure for the die stack 124, and may be formed for example of solid epoxy resin, Phenol resin, fused silica, crystalline silica, carbon black and/or metal hydroxide. Such mold compounds are available for example from Sumitomo Corp. and Nitto-Denko Corp., both having headquarters in Japan. Other mold compounds from other manufacturers are contemplated. The mold compound may be applied according to various known processes, including by FFT (Flow Free Thin) molding techniques.

Once the semiconductor cube assembly 100 is encapsulated in step 214, the carrier 106 may be removed in step 216. The release layer 108 may be heated or chemically treated to allow easy removal of the carrier 106.

In step 218, the semiconductor cube assembly 100 may be cut, or singulated, with cuts made in the x-z plane through the block of molding compound 144 as indicated by the dashed lines 146 in FIG. 5. The cut along dashed lines 146 may be made in the spaces 114 to separate the semiconductor die stack 124 from the wire bond landing blocks 104. Once separated from the semiconductor die stack 124, the wire bond landing blocks 104 may be discarded. The remaining encapsulated die stack 124 may be referred to herein as the semiconductor cube 160. The cuts along dashed lines 146 creates a pair of opposed, planar sidewalls 150 in semiconductor cube 160, one of which is visible in FIG. 6.

The cuts along dashed lines 146 may also be made through the pads 132 and blank 130, leaving a portion of the pads 132 and blank 130 exposed in the sidewalls 150 of the semiconductor cube 160 as seen in FIG. 6. It is understood that the controller die 136 may have other electrical interconnects which terminate in the sidewall 150 in further embodiments. For example, FIG. 5A shows a further embodiment where the blank 130 is lengthened relative to FIG. 5 and the pads 132 are positioned vertically over the wire bond landing blocks 104. In such an embodiment, when the cut is made along lines 146, the wire bonds 138 off of the controller die 136 (and not the pads 132) will be severed and will be exposed in the sidewall 150. In such an embodiment, the pads 132 are discarded with the rest of the wire bond landing blocks 104. As used herein, the electrical interconnects affixed to the die bond pads of the controller die 136 may include the pads 132 and/or the wire bonds 138.

The cuts along lines 146 also sever each of the wire bonds between the die 102 in stack 124 and the layers 105 of the respective wire bond landing blocks 104. As seen in FIG. 6, the severed ends of wire bonds 120 are exposed in sidewall 150. In embodiments including wire bonds 120 off of both opposed edges of the semiconductor die 102 in stack 124, the opposite sidewall 150 from that seen in FIG. 6 would also include the severed portions of pads 132 and the pattern of the severed ends of wire bonds 120. FIG. 6 also shows the pattern of solder bumps 140 on a surface of the semiconductor cube 160 adjacent the sidewalls 150.

The cuts along lines 146 may be performed by various cutting methods, including by saw blade, and produce highly planer sidewalls 150. The planarity and smoothness of sidewalls 150 may be increased in a polishing step 220, or multiple polishing steps 220 using successively smaller grains of grit in the polishing solution.

In steps 224-240, a pattern of electrical traces 162 may be formed on one or both sidewalls 150 as seen in FIG. 7 to electrically connect the controller die 136 to the semiconductor die 102 in the semiconductor cube 160. The electrical traces 162 are formed over, and lie in contact with, each column of severed wire bonds 120, as well as the pads 132 (or wire bond 138 in embodiments where wire bond 138 is severed at sidewall 150 instead of pads 132). Electrical traces 162 may also be formed extending between the trace columns as shown. The particular pattern of electrical traces 162 in FIG. 7 is a way of example only, and may be any of a wide variety of other patterns in further embodiments. As used herein, a pattern of electrical traces may be any pattern of electrical traces 162 extending between two or more severed wire bonds 120, pads 132 and/or wire bonds 138 (in embodiments where wire bond 138 is severed at sidewall 150 instead of pads 132). Such a pattern may comprise traces 162 extending between wire bonds from adjacent semiconductor die 102, and/or traces 162 extending between wire bonds from the same semiconductor die.

The pattern of electrical traces 162 may be formed by a variety of different steps. However, in one embodiment, in a step 224, a conductive seed layer may be applied to a sidewall 150. As the molding compound of sidewall 150 is in itself a dielectric insulator, there is no need to lay down and insulation layer beneath the conductive seed layer. The seed layer may be a thin film produced in a PVD (physical vapor deposition) process, and may for example be formed of titanium, nickel, copper or stainless steel sputtered onto the sidewall 150. The seed layer may be formed of other electrical conductors and may be applied by other thin film deposition techniques in further embodiments. The seed layer may be 2-5 μm, but may be thicker or thinner than that in further embodiments. Annealing heating may optionally be performed to purge a metal grain condition in the seed layer.

Next, the seed layer may be processed to remove portions of the layer and leave behind the desired pattern of electrical traces 162. In one example, a layer of photoresist may be spray coated over the seed layer (step 226). A pattern may be formed in the photoresist layer by the lithography (either a positive or negative image of the eventual electrical trace pattern), and the lithography pattern may be developed to expose the seed layer in the desired pattern through the photoresist (step 230). The exposed seed layer may be electroplated (step 232), and then the residual photoresist may be removed (step 234). A polyimide protective insulating layer may be coated and cured over the pattern of traces 162 (steps 238, 240). The pattern of electrical traces 162 may be formed by other photolithographic and non-photolithographic processes in further embodiments. One additional process is screen printing of the conductive traces in the shape of the electrical traces 162.

The pattern of electrical traces 162 connect the wire bonds 120 to the pads 132. As described above, pad 132 is in turn wire bonded internally to the die bond pads of the controller die 136. Thus, the system of electrical traces 162 and wire bonds 120 may effectively transfer signals between the controller die 136 and the semiconductor die 102 within the semiconductor cube 160. The semiconductor cube 160 may in turn be connected to a host device such as a printed circuit board having a pattern of contacts matching the pattern of solder bumps 140. The pattern of solder bumps 140 shown in FIGS. 6 and 7 is a way of example only and may vary in further embodiments. The solder bumps 140 may be reflowed onto the host device to couple the semiconductor cube 160 to the host device, and to allow the transfer of signals between the host device and the semiconductor cube 160.

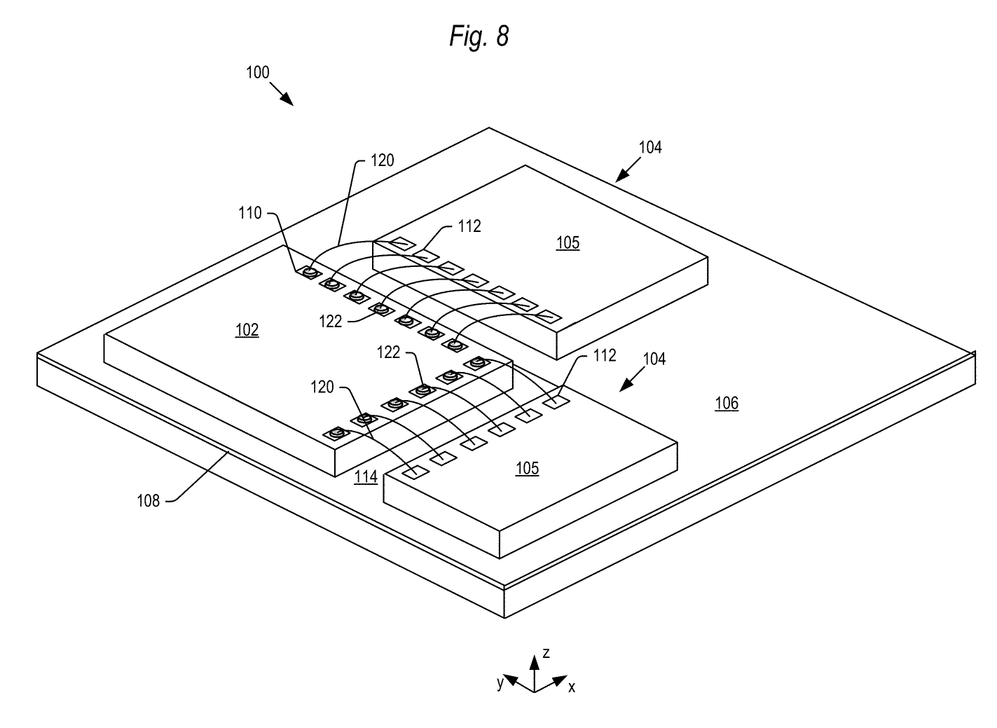

As noted, the wire bond landing blocks 104, and pattern of electrical traces 162, may be formed on one side or on two opposed sides of the semiconductor cube 160. FIGS. 8-10 illustrate an alternative embodiment, where the landing blocks 104, and the pattern of electrical traces 162, are provided on two adjacent sides of the semiconductor cube 160. As shown in FIG. 8, in this embodiment, die bond pads 110 are formed on two adjacent sides of the semiconductor die 102. As such, wire bond landing blocks 104 may be provided on carrier 106 in positions corresponding to the two adjacent sides of die 102 having the die bond pads 110. The die stack 124 and wire bond landing blocks 104 may be built up in successive layers and wire bonded as described above. A blank 130 and a controller die 136 be mounted on top of the die stack 124 as described above. And, the semiconductor cube assembly 100 may be encapsulated as described above.

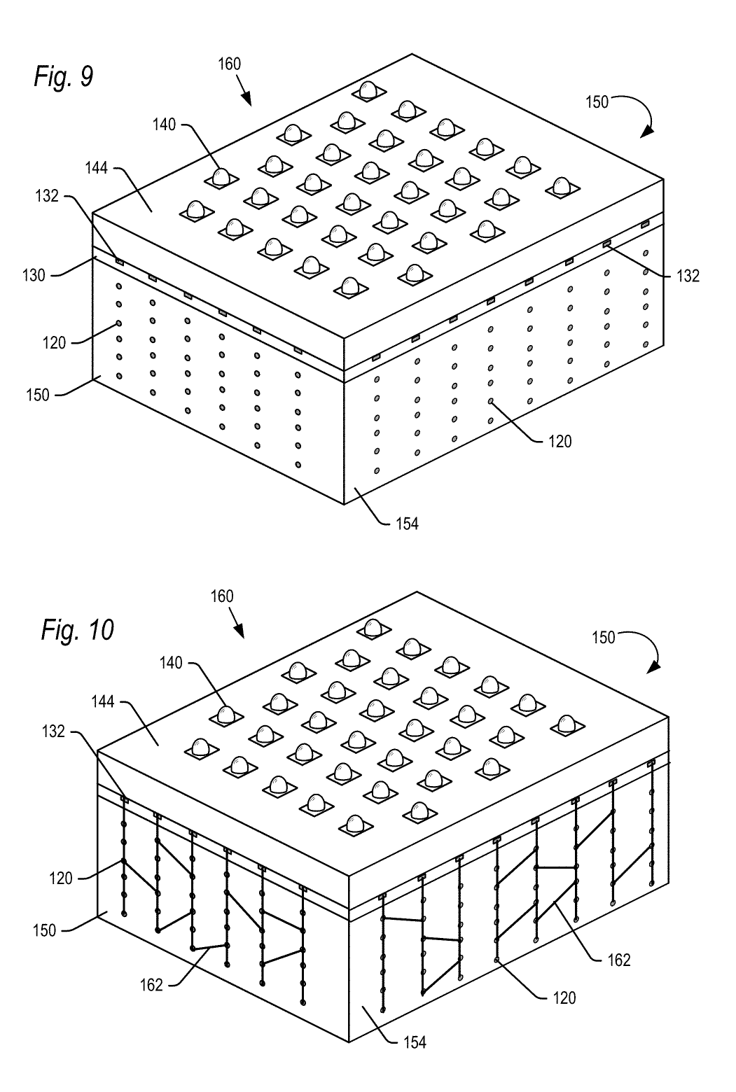

The semiconductor cube assembly 100 according to this embodiment may be cut along two adjacent (orthogonal) edges as shown in FIG. 9, to provide a sidewall 150 as described above and an adjacent sidewall 154. These sidewalls may be polished as described above, and wire bonds 120 and pads 132 may be exposed in the two orthogonal sidewalls as shown in FIG. 9. As shown in FIG. 10, electrical traces 162 may be formed on the two orthogonal sidewalls as described above in steps 224-240.

It is understood that die bond pads 110 may be provided around one edge, two adjacent or opposed edges, three edges or all four edges of semiconductor die 102. Wire bond landing blocks 104 as described above may be provided adjacent each edge including die bond pads 110. Similarly, a finished semiconductor cube 160 may include severed wire bonds exposed at one sidewall, two adjacent or opposed sidewalls, three sidewalls or all four sidewalls, depending on the die bond pad configuration on the die 102 in the die stack 124.

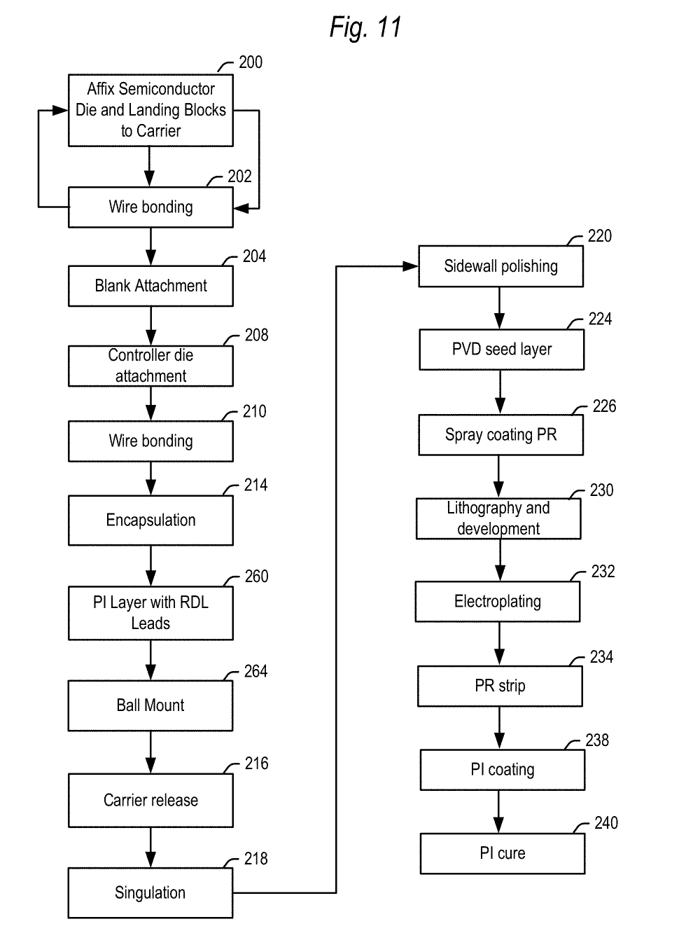

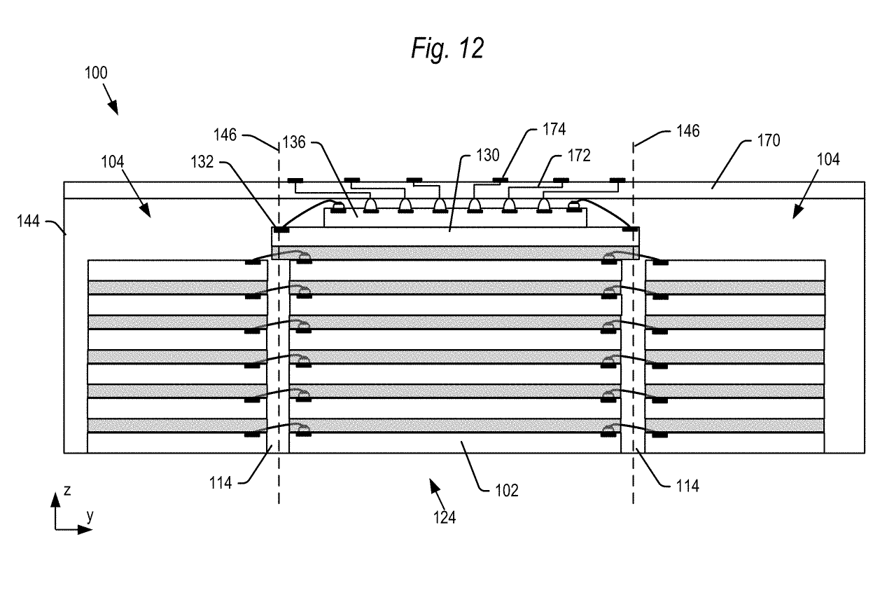

FIGS. 6-10 illustrate one example of electrical connectors (solder bumps 140) enabling communication between the semiconductor cube 160 and a host device such as a PCB. It is understood that the semiconductor cube 160 may include other configurations of electrical connectors enabling communication between the semiconductor cube 160 and a host device. One such further example is shown and described with respect to the flowchart of FIG. 11 and the views of FIGS. 12-14.

In the flowchart of FIG. 11, steps having the same reference numbers as is FIG. 1 are the same steps as in FIG. 1. A semiconductor cube assembly 100 may be assembled with the die stack 124 and wire bond landing blocks 104 being built up in successive layers and wire bonded as described above (steps 200, 202). A blank 130 and a controller die 136 may be mounted on top of the die stack 124 as described above (steps 204-210). And, the semiconductor cube assembly 100 may be encapsulated as described above (step 214).

The controller die 136 may include a pattern of contact pads on an upper surface, which contact pads are exposed through the mold compound 144. The mold compound 144 may initially cover these contact pads and the mold compound may then be etched to expose these contact pads, or the contact pads may remain uncovered by mold compound during the encapsulation process.

In step 260, a polyimide layer 170 may be affixed to an upper surface of the semiconductor cube assembly 100 as shown in FIG. 12. The polyimide layer 170 may include a pattern of electrical contacts matching the pattern of electrical contacts on the upper surface of the controller die 136. The electrical contacts on the polyimide layer 170 and controller die 136 may mate together when the polyimide layer 170 is affixed to the semiconductor cube 160 (solder may be provided on one or the other of the contacts of the polyimide layer 170 and controller die 136 to facilitate bonding of the contact pads).

As shown in FIG. 12, the polyimide layer 170 may be an interposer layer for redistributing electrical contacts from a first (bottom) surface of the polyimide layer 170 to a second (top) surface of the polyimide layer. In particular, the polyimide layer 170 may include an internal lead structure 172 of electrical traces and/or vias connected at one end to the contact pads in the bottom surface of the polyimide layer 170, and at a second end to contact pads 174 on a top surface of the polyimide layer 170. The internal lead structure 172 is provided for redistributing the electrical contact locations from the bottom surface of the polyimide layer 170 the top surface. The pattern of the internal lead structure 172 is for illustrative purposes, and would vary in further embodiments.

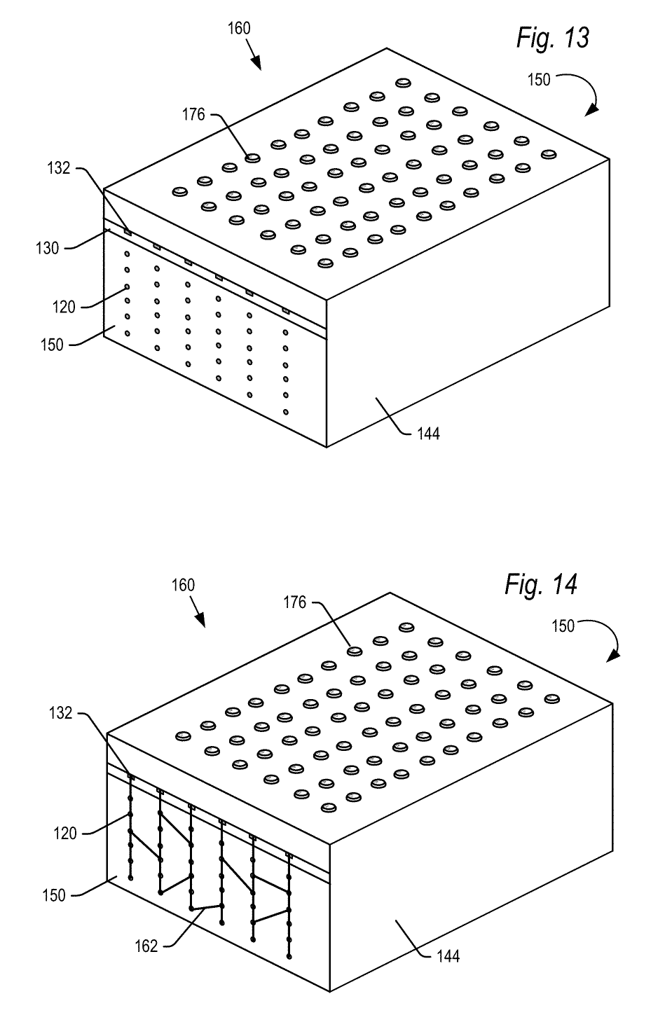

In step 264, solder balls 176 (FIG. 13) may be affixed to the contact pads 174 on the top surface of the polyimide layer 170. The solder balls 176 may be used to affix the semiconductor cube 160 to a host device such as a PCB, as well as to enable the transfer of signals between the host device and the semiconductor cube 160.

After formation of the solder balls, the remainder of the fabrication steps of semiconductor cube 160 may be performed according to any of the embodiments described above. The carrier may be released in step 216, and the semiconductor cube assembly 100 maybe singulated in step 218. The resulting exposed planar sidewalls (150 and/or 154) may be polished (step 220), and a pattern of electrical traces 162 may be formed on the planar sidewalls in steps 224-240 as described above. A finished semiconductor cube 160 according to this embodiment is shown in FIG. 14.

The cuts in the encapsulated semiconductor cube assembly 100 along lines 146 (FIGS. 5 and 11) may be made close to the semiconductor die 102 in the die stack 124. In one example, the mold compound 144 may extend 5 to 10 μm beyond the edges of the semiconductor die 102 in the stack 124, though the mold compound 144 may extend beyond the die stack edges to a greater or lesser extent in further embodiments. Thus, the footprint of the finished semiconductor cube 160 may closely approximate the footprint of a conventional semiconductor flash cube formed without mold compound 144. However, in accordance with aspects of the present technology, the sidewalls (150 and/or 154) may be highly planar. Thus, the present technology enables the formation of electrical traces on the sidewalls more effectively than conventional semiconductor cubes where the traces are formed on a vertical edge defined by semiconductor die in the cube.

Additionally, the controller die 136 is located at a top of the cube 160, near to a connection point of the cube 160 with a host device. This minimizes the interconnection distance between the controller die 136 and the host device, which in turn can reduce loss and crosstalk, and improve the signal transfer speed.

In summary, the present technology relates to a semiconductor cube, comprising: one or more semiconductor die, the one or more semiconductor die including die bond pads; wire bonds having first ends affixed to the die bond pads; a protective enclosure enclosing the one or more semiconductor die, the wire bonds having second ends, opposite the first ends, terminating at a sidewall of the protective enclosure; and a pattern of electrical traces on the sidewall, electrically coupled to the second ends of the wire bonds terminating at the sidewall.

In another example, the present technology relates to a semiconductor cube, comprising: a plurality of stacked semiconductor die comprising a first set of die bond pads; wire bonds having first ends affixed to the first set of die bond pads; a controller die comprising a second set of die bond pads; electrical interconnects coupled to the second set of die bond pads; a protective enclosure enclosing the one or more semiconductor die, the wire bonds having a second end, opposite the first end, terminating at a sidewall of the protective enclosure, and the electrical interconnects having a portion terminating at the sidewall; and a pattern of electrical traces on the sidewall in physical contact with the second ends of the wire bonds terminating at the sidewall and in physical contact with the portion of the electrical interconnects terminating at the sidewall.

In a further example, the present technology relates to a method of fabricating a semiconductor cube comprising a plurality of stacked semiconductor die and wire bonds having a first end coupled to the plurality of semiconductor die and a second end, opposite the first end, terminating at a sidewall of the semiconductor cube, the method comprising: (a) forming wire bonds between a semiconductor die of the stacked semiconductor die and a wire bond landing block; (b) encapsulating the stacked semiconductor die, wire bonds and at least a portion of the wire bond landing block in a protective enclosure to form a semiconductor cube assembly; (c) cutting the semiconductor cube assembly to separate the stacked semiconductor die from the wire bond landing block and severing the wire bonds in a sidewall of the semiconductor cube; and (d) forming electrical traces on the sidewall interconnecting the severed wire bonds.

In a further example, the present technology relates to a semiconductor cube, comprising: one or more semiconductor die, the one or more semiconductor die including die bond pads; wire bond means having first ends affixed to the die bond pads; a protective enclosure means enclosing the one or more semiconductor die, the wire bond means having second ends, opposite the first ends, terminating at a sidewall of the protective enclosure means; and electrical trace means on the sidewall, electrically coupled to the second ends of the wire bond means terminating at the sidewall.

The foregoing detailed description of the technology has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

We claim:

1. A semiconductor cube, comprising:
one or more semiconductor die, the one or more semiconductor die including die bond pads;
wire bonds having first ends affixed to the die bond pads;
a protective enclosure enclosing the one or more semiconductor die, the wire bonds having second ends, opposite the first ends, terminating at a sidewall of the protective enclosure; and
a pattern of electrical traces on the sidewall, electrically coupled to the second ends of the wire bonds terminating at the sidewall.

2. The semiconductor cube of claim 1, wherein the one or more semiconductor die comprise a plurality of semiconductor die stacked with respect to each other.

3. The semiconductor cube of claim 2, wherein the die bond pads comprise a column of die bond pads, the column of die bond pads comprising one die bond pad from each of the plurality of semiconductor die, and wherein the second ends of the wire bonds connected to the die bond pads in the column of die bond pads terminate in a column on the sidewall.

4. The semiconductor cube of claim 3, wherein the pattern of electrical traces comprise a first electrical trace connecting the second ends of the wire bonds in the column on the sidewall.

5. The semiconductor cube of claim 1, wherein the one or more semiconductor die comprise a plurality of flash memory die.

6. The semiconductor cube of claim 5, further comprising a controller die electrically coupled to the plurality of flash memory die via the wire bonds and the pattern of electrical traces.

7. The semiconductor cube of claim 1, wherein the one or more semiconductor die comprise a plurality of vertically stacked semiconductor die.

8. The semiconductor cube of claim 7, further comprising a controller die mounted within the protective enclosure on top of the vertically stacked semiconductor die.

9. The semiconductor cube of claim 8, wherein the controller die includes an electrical interconnect electrically connected to die bond pads on the controller die and terminating in the sidewall.

10. The semiconductor cube of claim 9, wherein the pattern of electrical traces electrically connect a second end of a wire bond from the one or more semiconductor die with the electrical interconnects from the controller die at the sidewall.

11. The semiconductor cube of claim 9, wherein the electrical interconnects comprise a pad.

12. The semiconductor cube of claim 9, wherein the electrical interconnects comprise a wire bond.

13. The semiconductor cube of claim 1, further comprising electrical connectors on a surface of the semiconductor cube adjacent the sidewall configured to affix the semiconductor cube to a host device.

14. The semiconductor cube of claim 13, wherein the electrical connectors comprises an array of solder bumps or balls.

15. A semiconductor cube, comprising:
a plurality of stacked semiconductor die comprising a first set of die bond pads;
wire bonds having first ends affixed to the first set of die bond pads;
a controller die comprising a second set of die bond pads;
electrical interconnects coupled to the second set of die bond pads;
a protective enclosure enclosing the one or more semiconductor die, the wire bonds having a second end, opposite the first end, terminating at a sidewall of the protective enclosure, and the electrical interconnects having a portion terminating at the sidewall; and
a pattern of electrical traces on the sidewall in physical contact with the second ends of the wire bonds terminating at the sidewall and in physical contact with the portion of the electrical interconnects terminating at the sidewall.

16. The semiconductor cube of claim 15, wherein the electrical interconnects comprise pads terminating at the sidewall.

17. The semiconductor cube of claim 15, wherein the electrical interconnects comprise wire bonds terminating at the sidewall.

18. The semiconductor cube of claim 15, wherein the pattern of electrical traces electrically connect the wire bonds from the plurality of semiconductor die with the electrical interconnects from the controller die.

19. The semiconductor cube of claim 15, wherein the die bond pads comprise a column of die bond pads, the column of die bond pads comprising one die bond pad from each of the plurality of semiconductor die, and wherein the second ends of the wire bonds connected to the die bond pads in the column of die bond pads terminate in a row on the sidewall.

20. The semiconductor cube of claim 19, wherein the pattern of electrical traces comprise a first electrical trace connecting the second ends of the wire bonds in the row on the sidewall.

21. The semiconductor cube of claim 20, wherein the first electrical trace connects with the portion of the electrical interconnects from the controller die at the sidewall.

22. A method of fabricating a semiconductor cube comprising a plurality of stacked semiconductor die and wire bonds having a first end coupled to the plurality of semiconductor die and a second end, opposite the first end, terminating at a sidewall of the semiconductor cube, the method comprising:
(a) forming wire bonds between a semiconductor die of the stacked semiconductor die and a wire bond landing block;
(b) encapsulating the stacked semiconductor die, wire bonds and at least a portion of the wire bond landing block in a protective enclosure to form a semiconductor cube assembly;
(c) cutting the semiconductor cube assembly to separate the stacked semiconductor die from the wire bond landing block and severing the wire bonds in a sidewall of the semiconductor cube; and
(d) forming electrical traces on the sidewall interconnecting the severed wire bonds.

23. The method of claim 22, further comprising the steps of:
building a first layer of the stacked semiconductor die and wire bond landing block by mounting a first semiconductor die adjacent a first layer of the wire bond landing block;
forming the wire bonds of the step (a) on the first layer;
encasing the wire bonds in a film; and
building a second layer of the stacked semiconductor die and wire bond landing block on top of the film.

24. A semiconductor cube, comprising:
one or more semiconductor die, the one or more semiconductor die including die bond pads;
wire bond means having first ends affixed to the die bond pads;
a protective enclosure means enclosing the one or more semiconductor die, the wire bond means having second ends, opposite the first ends, terminating at a sidewall of the protective enclosure means; and
electrical trace means on the sidewall, electrically coupled to the second ends of the wire bond means terminating at the sidewall.
